(19) United States
(12) Patent Application Publication
(10) Pub. No.: US 2021/0265539 A1
(43) Pub. Date: Aug. 26, 2021

(54) Semiconlight Light Emitting Diode

(71) Applicant: SEMICON LIGHT CO., LTD., Gyeonggi-do (KR)

(72) Inventors: Eun Hyun PARK, Gyeonggi-do (KR); Kyoung Min KIM, Gyeonggi-do (KR); Bong Hwan KIM, Gyeonggi-do (KR)

(73) Assignee: SEMICON LIGHT CO., LTD.

(21) Appl. No.: 16/984,766

(22) Filed: Aug. 4, 2020

(30) Foreign Application Priority Data
Feb. 24, 2020 (KR) 10-2020-0022312

(51) Int. Cl. H01L 33/58; H01L 25/075; H01L 33/62

(52) U.S. Cl. CPC H01L 33/58; H01L 33/62; H01L 25/0753

(57) ABSTRACT

Disclosed is a semiconductor light emitting device comprising: an external substrate; a first semiconductor light emitting device chip provided on the external substrate, comprising a first plurality of semiconductor layers including a first active layer for generating ultraviolet light by recombination of electrons and holes, and a first electrode electrically connected to the first plurality of semiconductor layers; a lens configured to surround the first semiconductor light emitting device chip, the lens serving to refract the ultraviolet light from the first semiconductor light emitting device chip and forming an orientation angle within a predefined range; and, a second semiconductor light emitting device chip provided on the external substrate, the second semiconductor light emitting device comprising a second plurality of semiconductor layers including a second active layer for generating visible light by recombination of electrons and holes, and a second electrode electrically connected to the second plurality of semiconductor layers.

### CROSS REFERENCE TO RELATED APPLICATION

This application claims the benefit of and priority to Korean Patent Application No. 10-2020-0022312, filed on Feb. 24, 2020. The entire disclosure of the application identified in this paragraph is incorporated herein by reference.

### FIELD

The present disclosure relates generally to a semiconductor light emitting device, and more particularly, to a semiconductor light emitting device with higher efficiency of light emission.

### BACKGROUND

This section provides background information related to the present disclosure which is not necessarily prior art.

FIG. 1 shows an example of a semiconductor light emitting device chip in the art.

The semiconductor light emitting device chip includes a growth substrate 610 (e.g. a sapphire substrate), and a stack of layers sequentially deposited on the growth substrate 610 that includes a buffer layer 620, a first semiconductor layer 630 having a first conductivity (e.g. an n-type GaN layer), an active layer 640 for generating light by electron-hole recombination (e.g. an InGaN/(In)/GaN multiple quantum well (MQW) structure), and a second semiconductor layer 650 having a second conductivity different from the first conductivity (e.g. a p-type GaN layer). The semiconductor light emitting device further includes a light transmitting conductive film 660 for current spreading formed on the second semiconductor layer 650, an electrode 670 serving as a bonding pad formed on the light transmitting conductive film 660, and an electrode 680 serving as a bonding pad (e.g. Cr/Ni/Au metallic pads stacked) formed on an etched exposed portion of the first semiconductor layer 630. This particular type of the semiconductor light emitting device as shown in FIG. 1 is called a lateral chip. Here, one side of the growth substrate 610 serves as a mounting face for electrical connections to outside. In the context herein, the term “outside” to which a semiconductor light emitting device chip or a semiconductor light emitting device is electrically connected denotes a PCB (Printed Circuit Board), a submount, a TFT (Thin Film Transistor) or the like.

FIG. 2 shows another example of a semiconductor light emitting device chip disclosed in U.S. Pat. No. 7,262,436. For easier reference in the following description, similar components may have same or different reference numerals as appropriate.

The semiconductor light emitting device chip includes a growth substrate 610, a stack of layers sequentially deposited on the growth substrate 610 that includes a first semiconductor layer 630 having a first conductivity, an active layer 640 adapted to generate light by electron-hole recombination and a second semiconductor layer 650 having a second conductivity different from the first conductivity, followed by a three-layered electrode 690, 691 and 692 adapted to reflect light towards the growth substrate 610, in which the three-layered electrode includes a first electrode layer 690 such as a reflective Ag layer, a second electrode layer 691 such as a Ni diffusion barrier, and a third electrode layer 692 such as an Au bonding layer, for example. Next, an electrode 680 serving as a bonding pad is formed on an etch-exposed portion of the first semiconductor layer 630. Here, one side of the electrode layer 692 serves as a mounting face for electrical connections to outside. This particular type of the semiconductor light emitting device chip shown in FIG. 2 is called a flip chip. In this flip chip, the electrode 680 formed on the first semiconductor layer 630 is provided at a lower height level than the electrode layers 690, 691 and 692 formed on the second semiconductor layer, but alternatively all of them may be formed at an even height. Here, height levels are given with respect to the growth substrate 610.

FIG. 3 shows an example of a semiconductor light emitting device 700 in the art.

The semiconductor light emitting device 700 has lead frames 710 and 720, a mold 730, and a vertical type light-emitting device chip 750 in a cavity 740 filled with an encapsulating member 770 that contains a wavelength converting material 160. The lower face of the vertical type light-emitting device chip 750 is directly electrically connected to the lead frame 710, and the upper face thereof is electrically connected to the lead frame 720 by a wire 780. A portion of the light coming out of the vertical type light-emitting device chip 750 excites the wavelength converting material 760 such that lights of different colors are generated, and white light is produced by mixing two different lights. For instance, the semiconductor light emitting device chip 750 generates blue light, and the wavelength converting material 760 is excited to generate yellow light. Then these blue and yellow lights can be mixed to produce white light. While the semiconductor light emitting device shown in FIG. 3 is produced using the vertical type light emitting device chip 750, other types of semiconductor light emitting devices similar to the one in FIG. 3 may also be produced using the semiconductor light emitting device chips illustrated in FIG. 1 and FIG. 2.

Such a semiconductor light emitting device described in FIG. 3 is generally referred to as a package type semiconductor light emitting device, and a semiconductor light emitting device with the size of a chip is referred to as a CSP (Chip Scale Package) type semiconductor light emitting device. Description relevant to CSP type semiconductor light emitting devices can be found in Korean Patent Laid-Open Publication No. 10-2014-0127457. To keep abreast with high demands for a smaller size semiconductor light emitting device, more studies on CSP type semiconductor light emitting devices are currently underway.

FIG. 4 shows an example of a front-load drum washer 800 described in Korean Patent Laid-Open Publication No. 10-2008-0074538.

The front-load drum washer 800 includes a gasket 815 provided between the entrance of a drum 825 and a door 812.

The gasket 815 has a UV generation unit 850 for emitting UV rays towards the interior of the drum 825. The front-load drum washer 800 also includes an illumination unit 860 which is arranged at one side of the gasket 815 to radiate visible light towards the interior of the drum 825. The activation of the UV generation unit 850 is signaled to the user through light of a different color turned on the illumination unit 860.

In FIG. 4, as the UV generation unit 850 and the illumination unit 850 have their own spaces, the space efficiency of use may need to be improved. In addition, the UV generation unit 850 and the illumination unit 850 are provided as separate parts, which require additional electrical connection to control both simultaneously.

The purposes of the disclosure will be described at the last part of the specification.

### SUMMARY

This section provides a general summary of the disclosure and is not comprehensive disclosure of its full scope or all of its features.

According to one aspect of the present disclosure, there is provided a semiconductor light emitting device comprising: an external substrate; a first semiconductor light emitting device chip provided on the external substrate, the first semiconductor light emitting device chip comprising a first plurality of semiconductor layers including a first active layer for generating ultraviolet light by recombination of electrons and holes, and a first electrode electrically connected to the first plurality of semiconductor layers; a lens configured to surround the first semiconductor light emitting device chip, the lens serving to refract the ultraviolet light from the first semiconductor light emitting device chip and forming an orientation angle within a predefined range; and, a second semiconductor light emitting device chip provided on the external substrate, the second semiconductor light emitting device comprising a second plurality of semiconductor layers including a second active layer for generating visible light by recombination of electrons and holes, and a second electrode electrically connected to the second plurality of semiconductor layers, wherein the second semiconductor light emitting device chip is positioned outside the predefined range of the orientation angle formed by the ultraviolet light refracted by the lens, wherein the external substrate includes a conductive layer electrically connected to the first electrode of the first semiconductor light emitting device chip and the second electrode of the second semiconductor light emitting device chip.

The effects of the disclosure will be described at the last part of the specification.

### BRIEF DESCRIPTION OF THE DRAWINGS

FIG. 1 shows an example of a semiconductor light emitting device chip in the art.

FIG. 2 shows another example of a semiconductor light emitting device chip disclosed in U.S. Pat. No. 7,262,436.

FIG. 3 shows an example of a semiconductor light emitting device in the art.

FIG. 4 shows an example of a front-load drum washer 800 described in Korean Patent Laid-Open Publication No. 10-2008-0074538.

FIGS. 5A and 5B show an exemplary embodiment of a semiconductor light emitting device according to the present disclosure.

FIGS. 6A and 6B show another exemplary embodiment of a semiconductor light emitting device according to the present disclosure.

FIGS. 7A and 7B show another exemplary embodiment of a semiconductor light emitting device according to the present disclosure.

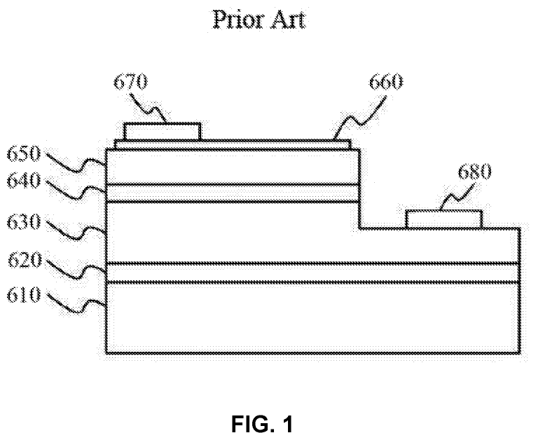

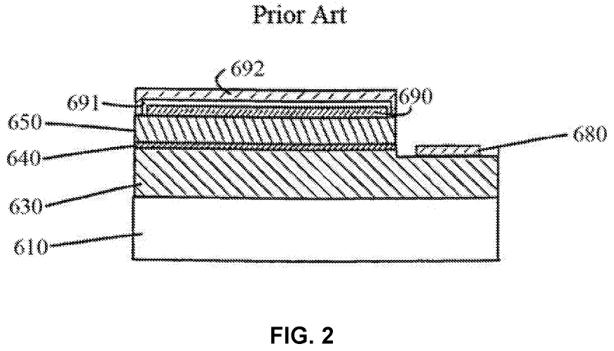

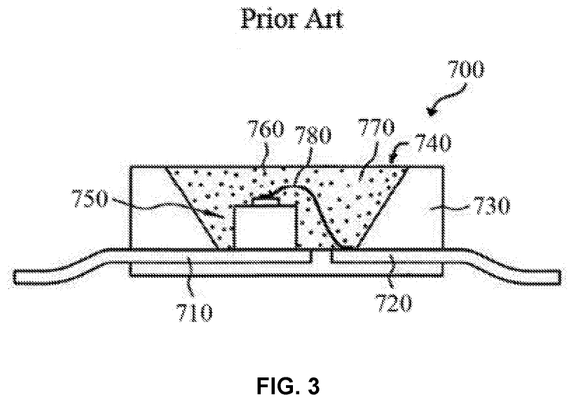

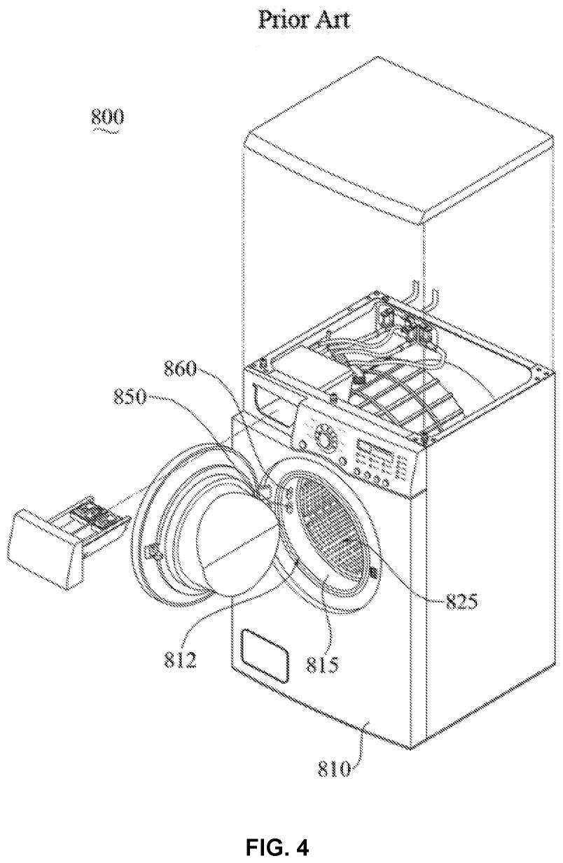

### DETAILED DESCRIPTION

The present disclosure will now be described in detail with reference to the accompanying drawings.

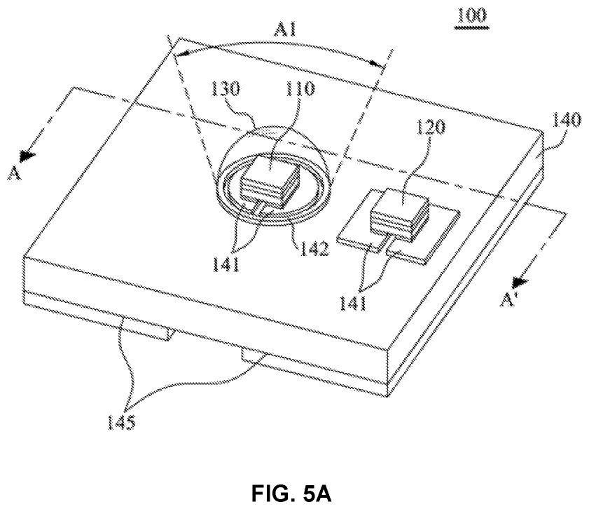

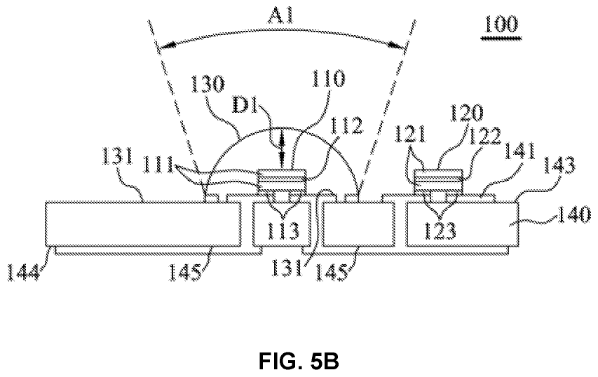

FIG. 5 shows an exemplary embodiment of a semiconductor light emitting device 100 according to the present disclosure.

FIG. 5A is a perspective view of the semiconductor light emitting device 100, and FIG. 5B is a cross sectional view taken along line AA′ in FIG. 5A.

The semiconductor light emitting device 100 includes a first semiconductor light emitting device chip 110, a second semiconductor light emitting device chip 120, a lens 130, and an external substrate 140.

The first semiconductor light emitting device chip 110 emits ultraviolet light. It includes a plurality of semiconductor layers 111 and an active layer 112 that generates ultraviolet light by recombination of electrons and holes. The first semiconductor light emitting device chip 110 has an electrode 113 electrically connected to the plurality of semiconductor layers 111. The ultraviolet light emitted by the first semiconductor light emitting device chip 110 may be emitted in every direction of the first semiconductor light emitting device chip 110. The first semiconductor light emitting device chip 110 may be a flip chip but is not limited thereto. For example, the first semiconductor light emitting device chip 110 may be a lateral chip or a vertical chip.

The first semiconductor light emitting device chip 10 of the present disclosure preferably emits UVC rays, in particular, with wavelengths ranging from 200 nm to 280 nm.

The second semiconductor light emitting device chip 120 emits visible light. It includes a plurality of semiconductor layers 121 and an active layer 122 that generates ultraviolet light by recombination of electrons and holes. The second semiconductor light emitting device chip 1210 has an electrode 123 electrically connected to the plurality of semiconductor layers 121. The second semiconductor light emitting device chip 120 may be a flip chip but is not limited thereto. For example, the second semiconductor light emitting device chip 120 may be a lateral chip or a vertical chip.

The second semiconductor light emitting device chip 120 according to the present disclosure can emit blue light in the visible light spectrum. Additionally, or alternatively, the second semiconductor light emitting device chip 120 may also emit light of a different color in the visible light spectrum.

It is preferable that the first semiconductor light emitting device chip 110 and the second semiconductor light emitting device chip 120 concurrently emit ultraviolet light and visible light, respectively. With the ultraviolet light being invisible, it is not possible for the user to find out whether the ultraviolet light known to be harmful to the human body is being radiated, if only the first semiconductor light emitting device chip 110 has been turned on. Therefore, both the ultraviolet light and the visible light should be emitted at the same time by the first and second semiconductor light emitting device chips 110 and 120, allowing the user to be aware of the emission of ultraviolet light.

The external substrate 140 includes a conductive layer 141 on its upper portion. The conductive layer 141 is electrically connected to the electrode 113 of the first semiconductor light emitting device chip 110 and the electrode 123 of the second semiconductor light emitting device chip 120. The external substrate 140 is not particularly limited as far as it provides a mounting area for the first and second semiconductor light emitting device chips 110 and 120. Moreover, the external substrate 140 can be a substrate used for forming the first semiconductor light emitting device chip 110. For example, it can be a substrate including reed electrodes, a printed circuit board, or a metallic plate substrate. Moreover, the external substrate 140 may include an electrode 145 on its lower portion 144. The electrode 145 can be electrically connected to outside. The conductive layer 141 and the electrode 145 of the external substrate 140 may be electrically connected to each other.

The lens 130 is provided on the external substrate 140, surrounding the first semiconductor light emitting device chip 110. The ultraviolet light coming from the first semiconductor light emitting device chip 110 is reflected by the lens 130. The lens 130 has a hemispherical form, for example. The ultraviolet light from the first semiconductor light emitting device chip 110 is refracted by the lens 130 at an orientation angle A1. Here, the orientation angle A1 refers to an angle that is formed by the ultraviolet light after it has transmitted through the lens 130, rather than an angle that is formed by the ultraviolet light coming from the first semiconductor light emitting device chip 110.

Preferably, the top of the lens 130 is spaced away from the top face of the first semiconductor light emitting device chip 110 by a distance D1 of at least 200 μm to 600 μm.

When the first semiconductor light emitting device chip 110 and the second semiconductor light emitting device chip 120 are separated from each other by 120 μm or less, a second semiconductor light emitting device chip 120 can be provided inside the orientation angle A1 that is formed by the lens 130 surrounding the first semiconductor light emitting device chip 110, which enables the second semiconductor light emitting device chip 120 to absorb the ultraviolet light, possibly bringing down the efficiency of light emission.

The lens 130 may be a preformed glass or an encapsulating member, for example.

The external substrate 140 further includes a barrier 142. The barrier 142 is placed at a predefined distance away from the conductive layer 141 on the upper face of the external substrate 140. The barrier 142 can be made of a metal such as Ni, Pt, Pd, Rh, W, Ti, Al, Ag, Au or Cu. With this metallic barrier 142 being positioned at a certain distance from the conductive layer 141, any contact between them can be avoided, lowering the risk of an electrical short. The barrier 142 can be used as a stopper wall, i.e. a dam, for keeping the encapsulating member, which is provided as the lens 130, from running over the barrier 142. Alternatively, the barrier 142 can be omitted. The barrier 142 is preferably made of a material, which not only is firm or hard enough to maintain the shape of the lens 130 protecting the first semiconductor light emitting device chip 110, but which is also effective for avoiding cracks or splits.

The second semiconductor light emitting device chip 120 that is mounted on the external substrate 140 is provided outside the lens 130. The lens 130 can be arranged such that its lower face 131 may contact the upper face 143 or the conductive layer 141 of the external substrate 140, and the second semiconductor light emitting device chip 120 is provided on a portion of the upper face 143 or the conductive layer 141 of the external substrate 140, which is not in contact with the lens 130. The orientation angle A1 formed by the ultraviolet light from the first semiconductor light emitting device chip 120 after having been transmitted through the lens 130 as described above is preferably determined such that the ultraviolet light does not reach the second semiconductor light emitting device chip 120; otherwise, the ultraviolet light from the first semiconductor light emitting device chip 110 will be absorbed by the second semiconductor light emitting device chip 120. The orientation angle A1 of the ultraviolet light from the first semiconductor light emitting device chip 110 is preferably in the range from 130° to 155°.

Both the first semiconductor light emitting device chip 110 and the second semiconductor light emitting device chip 120 are preferably provided on the upper face 143 of the external substrate 140 and electrically connected, such that they can emit light at the same time. As the first semiconductor light emitting device chip 110 and the second semiconductor light emitting device chip 120 are electrically connected to the conductive layer 141 on the external substrate 140, it is possible to produce the semiconductor light emitting device 100 of a smaller size (area).

The semiconductor light emitting device 100 according to any of the embodiments of present disclosure has a size ranging from 3500 μm to 6000 μm, and the distance D1 between the top of the lens 130 and the first semiconductor light emitting device chip 110 ranges from 200 μm to 600 μm. Again, the orientation angle A1 of the ultraviolet light from the first semiconductor light emitting device chip 110 is in the range from 130° to 155°.

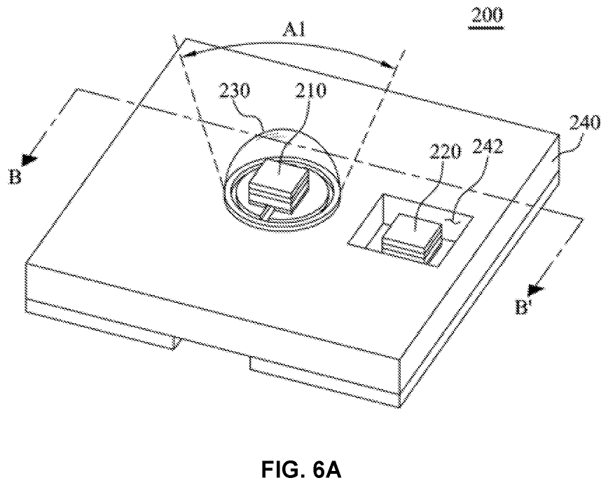

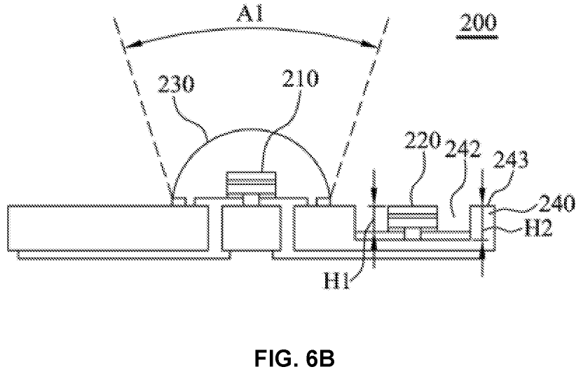

FIG. 6 shows another exemplary embodiment of a semiconductor light emitting device 200 according to the present disclosure.

FIG. 6A is a perspective view of the semiconductor light emitting device 200, and FIG. 6B is a cross sectional view taken along line BB′ in FIG. 6A.

The semiconductor light emitting device 200 may have on its external substrate 240 a recess 242 into which a second semiconductor light emitting device chip 220 is received. Again, as the second semiconductor light emitting device chip 220 should not be positioned within the range of the orientation angle A1 of the ultraviolet light refracted by the lens 230, the height H1 of the second semiconductor light emitting device chip 220 is determined accordingly, which in turn affects the location and depth H2 of the recess 242 for receiving the second semiconductor light emitting device chip 220 therein. For example, if the depth H2 of the recess 242 is deeper than the height H1 of the second semiconductor light emitting device chip 220, the second semiconductor light emitting device chip 220 will be at a lower height level than the upper face 243 of the external substrate 240, allowing the lens 230 and the recess 242 to come in contact with each other, regardless of the orientation angle A1.

The recess 242 is located aside the lens 230, with the recess 242 being positioned further outside on the external substrate 140.

Since the second semiconductor light emitting device chip 220 is not positioned within the range of the orientation angle A1 (i.e. out of the travel path) of the ultraviolet light from the first semiconductor light emitting device chip 210, the ultralight path can be emitted out of the semiconductor light emitting device 200 without interference.

In this embodiment, the semiconductor light emitting device 200 can be produced in a much smaller size by arranging the recess 242 and the lens 230 sufficiently close to each other. Further, the semiconductor light emitting device 200 has an increased efficiency of UV emission.

The semiconductor light emitting device 200 illustrated in FIG. 6 is substantially the same as the semiconductor light emitting device 100 illustrated in FIG. 5, except for the features described above with reference to FIG. 6.

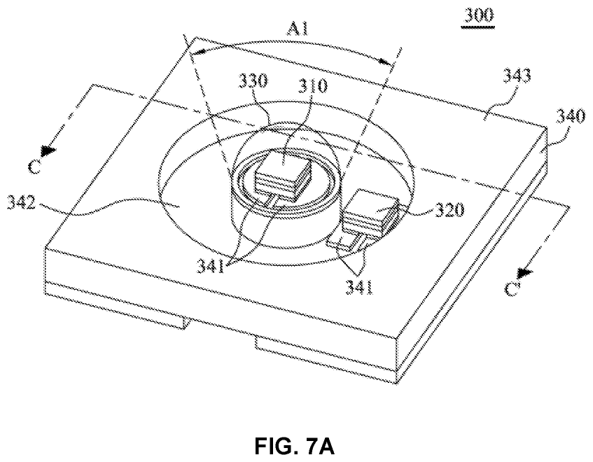

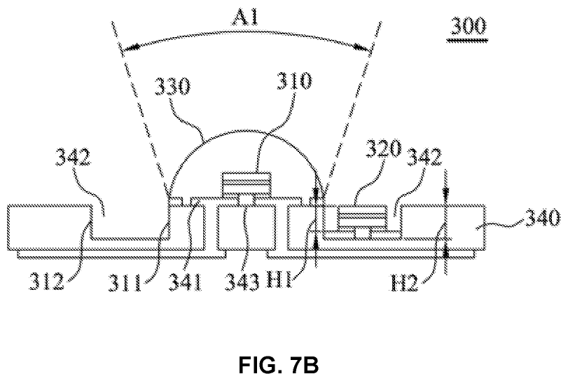

FIG. 7 shows another exemplary embodiment of a semiconductor light emitting device 300 according to the present disclosure.

FIG. 7A is a perspective view of the semiconductor light emitting device 300, and FIG. 7B is a cross sectional view taken along line CC′ in FIG. 7A.

The semiconductor light emitting device 300 may have on the upper face of the external substrate 340 a recess 342 into which a second semiconductor light emitting device chip 320 is received. The depth H2 of the recess 342 is preferably deeper than the height H1 of the second semiconductor light emitting device chip 320. In this way, the ultraviolet light from the first semiconductor light emitting device chip 310 will not be absorbed by the second semiconductor light emitting device chip 320 once it is inserted into the recess provided on the external substrate 340.

The recess 342 forms a closed loop that surrounds the first semiconductor light emitting device chip 310.

The recess 342 has an inner surface 311 formed closer towards the center of the semiconductor light emitting device 300, and an outer surface 312 formed further away from the center of the semiconductor light emitting device 300.

The lens 330 may be formed of an encapsulation member, which is made of a light-transmitting thermoplastic resin having at least 80% of UV transmissivity. The encapsulating member can create surface tension between the upper face 343 of the external substrate 340 and the inner surface 342 of the recess 342. Similar to a dam, the surface tension ensures that the encapsulation member would not be formed beyond or over the recess 342. The size of the lens 330 may be limited by the recess 342. While this embodiment illustrates a circular shaped recess 342 as seen on the plan view, the recess 342 can also take a quadrilateral shape as see on the plan view, provided that the second semiconductor light emitting device chip 320 is positioned outside the range of the orientation angle A1.

The semiconductor light emitting device 300 illustrated in FIG. 7 is substantially the same as the semiconductor light emitting device 100 illustrated in FIG. 5, except for the features described above with reference to FIG. 7.

Now, applicable embodiments of the present disclosure will be described.

(1) A semiconductor light emitting device comprising: an external substrate; a first semiconductor light emitting device chip provided on the external substrate, the first semiconductor light emitting device chip comprising a first plurality of semiconductor layers including a first active layer for generating ultraviolet light by recombination of electrons and holes, and a first electrode electrically connected to the first plurality of semiconductor layers; a lens configured to surround the first semiconductor light emitting device chip, the lens serving to refract the ultraviolet light from the first semiconductor light emitting device chip and forming an orientation angle within a predefined range; and, a second semiconductor light emitting device chip provided on the external substrate, the second semiconductor light emitting device comprising a second plurality of semiconductor layers including a second active layer for generating visible light by recombination of electrons and holes, and a second electrode electrically connected to the second plurality of semiconductor layers, wherein the second semiconductor light emitting device chip is positioned outside the predefined range of the orientation angle formed by the ultraviolet light refracted by the lens, wherein the external substrate includes a conductive layer electrically connected to the first electrode of the first semiconductor light emitting device chip and the second electrode of the second semiconductor light emitting device chip.

(2) There is also provided, the semiconductor light emitting device of clause (1) wherein the orientation angle ranges from 130° to 155°.

(3) There is also provided, the semiconductor light emitting device of clause (1) wherein the external substrate further comprises a recess for receiving the second semiconductor light emitting device chip.

(4) There is also provided, the semiconductor light emitting device of clause (3) wherein the recess is configured to surround the first semiconductor light emitting device chip.

(5) There is also provided, the semiconductor light emitting device of clause (1) wherein the second semiconductor light emitting device chip emits blue light.

(6) There is also provided, the semiconductor light emitting device of clause (3) wherein the lens and the recess are arranged, coming into contact with each other.

(7) There is also provided, the semiconductor light emitting device of clause (6) wherein the recess has a depth greater than the height of the second semiconductor light emitting device chip.

As discussed in the foregoing description, the semiconductor light emitting device according to an exemplary embodiment of the present disclosure has higher efficiency of UV emission.

Further, the semiconductor light emitting device according to another exemplary embodiment of the present disclosure includes the second semiconductor light emitting device chip positioned outside the range of the orientation angle of the ultraviolet light from either of the semiconductor light emitting device chips that are adapted to respectively emit visible light and ultraviolet light at the same time.

Further, the semiconductor light emitting device according to another exemplary embodiment of the present disclosure includes a lens adapted to control the orientation angle of the ultraviolet light.

### DESCRIPTION OF REFERENCE NUMERALS/SYMBOLS

100, 200, 300: Semiconductor light emitting device
110, 210, 310: First semiconductor light emitting device chip
120, 220, 320: Second semiconductor light emitting device chip
130, 230, 330: Lens
140, 240, 340: External substrate
242, 342: Recess

What is claimed is:

1. A semiconductor light emitting device comprising:
an external substrate;
a first semiconductor light emitting device chip provided on the external substrate, the first semiconductor light emitting device chip comprising a first plurality of semiconductor layers including a first active layer for generating ultraviolet light by recombination of electrons and holes, and a first electrode electrically connected to the first plurality of semiconductor layers;
a lens configured to surround the first semiconductor light emitting device chip, the lens serving to refract the ultraviolet light from the first semiconductor light emitting device chip and forming an orientation angle within a predefined range; and,
a second semiconductor light emitting device chip provided on the external substrate, the second semiconductor light emitting device comprising a second plurality of semiconductor layers including a second active layer for generating visible light by recombination of electrons and holes, and a second electrode electrically connected to the second plurality of semiconductor layers, wherein the second semiconductor light emitting device chip is positioned outside the predefined range of the orientation angle formed by the ultraviolet light refracted by the lens,
wherein the external substrate includes a conductive layer electrically connected to the first electrode of the first semiconductor light emitting device chip and the second electrode of the second semiconductor light emitting device chip.

2. The semiconductor light emitting device of claim 1, wherein the orientation angle ranges from 130° to 155°.

3. The semiconductor light emitting device of claim 1, wherein the external substrate further comprises a recess for receiving the second semiconductor light emitting device chip.

4. The semiconductor light emitting device of claim 3, wherein the recess is configured to surround the first semiconductor light emitting device chip.

5. The semiconductor light emitting device of claim 1, wherein the second semiconductor light emitting device chip emits blue light.

6. The semiconductor light emitting device of claim 3, wherein the lens and the recess are arranged, coming into contact with each other.

7. The semiconductor light emitting device of claim 6, wherein the recess has a depth greater than the height of the second semiconductor light emitting device chip.
